(19) United States
(12) Patent Application Publication
(10) Pub. No.: US 2019/0296729 A1
(43) Pub. Date: Sep. 26, 2019

(54) DRIVE DEVICE

(71) Applicant: DENSO CORPORATION, Kariya-city (JP)

(72) Inventor: Akira KAWAMOTO, Kariya-city (JP)

(21) Appl. No.: 16/424,646

(22) Filed: May 29, 2019

Related U.S. Application Data
(63) Continuation of application No. PCT/JP2017/033281, filed on Sep. 14, 2017.

(30) Foreign Application Priority Data
Dec. 1, 2016 (JP) 2016-234094

(51) Int. Cl. H03K 17/082; H02P 7/03; H02M 1/08

(52) U.S. Cl. CPC H03K 17/0822; H02M 1/08; H02P 7/04

(57) ABSTRACT

A drive device controls driving of an opening/closing metal-oxide-semiconductor (MOS) transistor and a protection MOS transistor that are interposed in series in a power supply path extending from a direct current power supply to a load and are connected so that parasitic diodes of the opening/closing MOS transistor and the protection MOS transistor are directed oppositely to each other. The drive device includes: a drive portion that operates by receiving power supplied from the direct current power supply via a high potential side power supply line and a low potential side power supply line, and drives the opening/closing MOS transistor and the protection MOS transistor; and a reverse connection protection controller that executes a protection operation which cuts off a current flowing in the power supply path by turning off the protection MOS transistor.

### CROSS REFERENCE TO RELATED APPLICATION

The present application is a continuation application of International Patent Application No. PCT/JP2017/033281 filed on Sep. 14, 2017, which designated the U.S. and claims the benefit of priority from Japanese Patent Application No. 2016-234094 filed on Dec. 1, 2016. The entire disclosures of all of the above applications are incorporated herein by reference.

### TECHNICAL FIELD

The present disclosure relates to a drive device which controls driving of an opening/closing metal-oxide-semiconductor (MOS) transistor and a protection MOS transistor both interposed in series in a power supply path extending from a direct current power supply to a load.

### BACKGROUND

When a positive terminal and a negative terminal of a battery, which is a power supply, are reversely connected (referred to as reverse connection) in a drive device which controls driving of a motor or the like, an excessive reverse current may flow. This current flow may break circuit elements such as transistors. For protecting the circuit elements from the reverse current, a configuration currently disclosed includes a protection MOS transistor connected such that a parasitic diode of the protection MOS transistor is directed oppositely to a parasitic diode of a power cutoff MOS transistor originally provided. In this case, the parasitic diode of the protection MOS transistor can cut off the reverse current.

### SUMMARY

The present disclosure may provide a drive device that controls driving of an opening/closing metal-oxide-semiconductor (MOS) transistor and a protection MOS transistor interposed in series in a power supply path extending from a direct current power supply to a load, and connected so that parasitic diodes of the opening/closing MOS transistor and the protection MOS transistor are directed oppositely to each other. The drive device is configured to: operate by receiving power supplied from the direct current power supply via a high potential side power supply line and a low potential side power supply line; drive the opening/closing MOS transistor and the protection MOS transistor; execute a protection operation which cuts off a current flowing in the power supply path by turning off the protection MOS transistor in response to that a potential relationship between the high potential side power supply line and the low potential side power supply line becomes a reverse potential relationship.

### BRIEF DESCRIPTION OF DRAWINGS

The above and other objects, features, and advantages of the present disclosure will become more apparent from the following detailed description with reference to the accompanying drawings. In the drawings:

FIG. 1 is a diagram schematically showing configurations of a drive device and a driven object of the drive device according to a first embodiment;

FIG. 2 is a diagram showing a specific configuration example of the drive device and the driven object of the drive device according to the first embodiment;

FIG. 3 is a diagram schematically showing a gate voltage of each transistor in a normal condition according to the first embodiment;

FIG. 4 is a diagram schematically showing a gate voltage of each transistor during reverse connection according to the first embodiment;

FIG. 5 is a diagram showing a specific configuration example of a drive device and a driven object of the drive device according to a second embodiment; and

FIG. 6 is a diagram showing a specific configuration example of a drive device and a driven object of the drive device according to a third embodiment.

### DETAILED DESCRIPTION

Current flowing during reverse connection in a configuration of a related technology may be difficult to cut off when power supplied to the load and power supplied to the drive device are not separated from each other. More specifically, the protection MOS transistor is difficult to control when power is not normally supplied to the drive circuit during reverse connection. In this case, the protection MOS transistor may be kept turned on, in which condition the reverse current may be difficult to cut off.

One aspect of the present disclosure may provide a drive device capable of securely cutting off a current flowing during reverse connection.

According to one aspect of the present disclosure, a drive device may control driving of an opening/closing metal-oxide-semiconductor (MOS) transistor and a protection MOS transistor interposed in series in a power supply path extending from a direct current power supply to a load and connected so that parasitic diodes of the opening/closing MOS transistor and the protection MOS transistor are directed oppositely to each other. The drive device may include: a drive portion that operates by receiving power supplied from the direct current power supply via a high potential side power supply line connected to a high potential side terminal of the direct current power supply and a low potential side power supply line connected to a low potential side terminal of the direct current power supply, and drives the opening/closing MOS transistor and the protection MOS transistor; and a reverse connection protection controller that executes a protection operation which cuts off a current flowing in the power supply path by forcibly turning off the protection MOS transistor independently of driving by the drive portion in response to that a potential relationship between the high potential side power supply line and the low potential side power supply line becomes a reverse potential relationship that is a reverse of a normal potential relationship between the high potential side power supply line and the low potential side power supply line.

According to the configuration, power supplied to the load and power supplied to the drive portion come from the same power supply. In this case, power may not be normally supplied to the drive portion when the direct current power supply is reversely connected. In this condition, the protection MOS transistor may be difficult to control. As a result, control of the protection MOS transistor by the drive portion may not be achieved. The protection MOS transistor may be therefore kept on-state, in which condition the reverse current is difficult to cut off.

Accordingly, the drive device further may include a reverse connection protection controller. When a potential relationship between a high potential side power supply line and a low potential side power supply line becomes a reverse potential relationship that is a reverse of a normal potential relationship between the high potential side power supply line and the low potential side power supply line, the reverse connection protection controller may forcibly turn off the protection MOS transistor even under driving by the drive portion to perform a protection operation for cutting off a current flowing through a power supply path.

In this configuration, at the time of reverse connection of the direct current power supply, the reverse connection protection controller may execute the protection operation when the potential relationship between the high potential side power supply line and the low potential side power supply line becomes the reverse potential relationship that is a reverse of the normal potential relationship. The protection MOS transistor may be turned off even when the drive portion does not normally operate. This condition achieves interruption of the path through which the reverse current generated by reverse connection flows. Accordingly, it may be possible to produce an excellent effect of reliable cutoff of the current flowing during reverse connection. Multiple embodiments will be described with reference to the drawings.

In the respective embodiments described herein, substantially identical components are given identical reference numerals, and are not repeatedly explained.

### First Embodiment

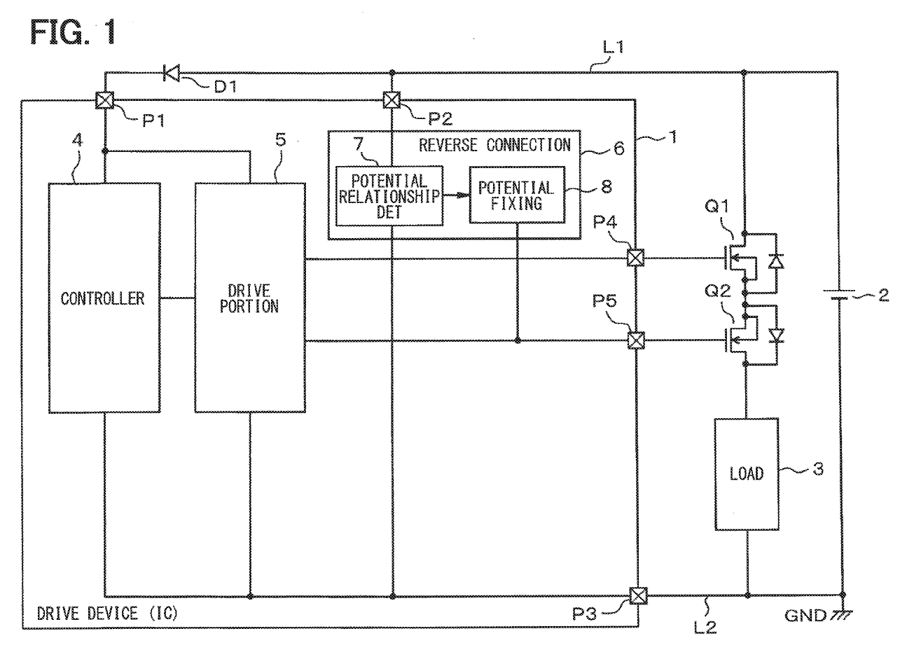

A first embodiment will be described with reference to FIGS. 1 to 4.

A drive device 1 shown in FIG. 1 controls driving of transistors Q1 and Q2 both interposed in series in a power supply path extending from a direct current power supply 2 to a load 3, and constitutes a semiconductor integrated circuit (IC).

The direct current power supply 2 is an in-vehicle battery, for example. A high potential side power supply line L1 (abbreviated as power supply line L1) is connected to a high potential side terminal of the direct current power supply 2, while a low potential side power supply line L2 (abbreviated as power supply line L2) is connected to a low potential side terminal of the direct current power supply 2. Each of the transistors Q1 and Q2 is an N channel type MOS transistor, and has a parasitic diode (body diode) connected between the drain and source of the transistor with the anode provided on the source side.

The drain of the transistor Q1 is connected to the power supply line L1, while the source of the transistor Q1 is connected to the source of the transistor Q2. The drain of the transistor Q2 is connected to the power supply line L2 via the load 3. In this manner, the transistors Q1 and Q2 are connected so that parasitic diodes of the transistors Q1 and Q2 are directed oppositely to each other. In this embodiment, the transistor Q1 corresponds to an opening/closing MOS transistor, while the transistor Q2 corresponds to a protection MOS transistor.

A terminal P1 of the drive device 1 is connected to the power supply line L1 via a diode D1 in a reverse direction. Terminals P2 and P3 of the drive device 1 are connected to the power supply lines L1 and L2, respectively. The drive device 1 includes a controller 4, a drive portion 5, and a reverse connection protection controller 6. The controller 4 and the drive portion 5 operate by receiving power supplied from the direct current power supply 2 via the terminals P1 and P3.

The drive portion 5 generates a gate driving signal for driving the transistors Q1 and Q2 in accordance with control signals supplied from the controller 4. These gate driving signals are applied to the gates of the transistors Q1 and Q2 via the terminals P4 and P5, respectively. The controller 4 controls operation of the drive portion 5 in a following manner. The controller 4 controls the operation of the drive portion 5 so that both the transistors Q1 and Q2 are turned on at the time of energization of the load 3.

When the potential relationship between the power supply lines L1 and L2 becomes a reverse potential relationship that is a reverse of a normal potential relationship between the power supply lines L1 and L2, the reverse connection protection controller 6 forcibly turns off the transistor Q2 even under driving by the drive portion 5 to execute a protection operation for cutting off a current flowing through the power supply path extending from the direct current power supply 2 to the load 3. The reverse connection protection controller 6 includes a potential relationship detection portion 7 and a potential fixing portion 8 both configured to implement this protection operation. Respective voltages of the power supply lines L1 and L2 are applied to the potential relationship detection portion 7 via the terminals P2 and P3. The potential relationship detection portion 7 divides the respective voltages, and detects the potential relationship between the power supply lines L1 and L2 based on the divided voltages.

When reverse connection of the direct current power supply 2 is not caused, i.e., in a normal condition, the potential relationship between the power supply lines L1 and L2 is expressed by following Expression (1). It is assumed that L1 and L2 in Expression (1) represent the potentials of the power supply lines L1 and L2, respectively.

L1 >L2 (1)

During the reverse connection when reverse connection of the direct current power supply 2 is caused, the potential relationship between the power supply lines L1 and L2 is expressed by following Expression (2).

L1<L2 (2)

In the following description, the relationship shown in Expression (1) will be referred to as a “normal potential relationship”, while the relationship shown in Expression (2) will be referred to as a “reverse potential relationship”. The potential relationship detection portion 7 detects the “normal potential relationship” or “reverse potential relationship” as the potential relationship between the power supply lines L1 and L2, and issues a signal indicating a detection result to the potential fixing portion 8.

When receiving a signal indicating the reverse potential relationship between the power supply lines L1 and L2 from the potential relationship detection portion 7, the potential fixing portion 8 fixes the gate potential of the transistor Q2 to the potential of the power supply line L1. As will be detailed below, the foregoing protection operation is achievable by this step.

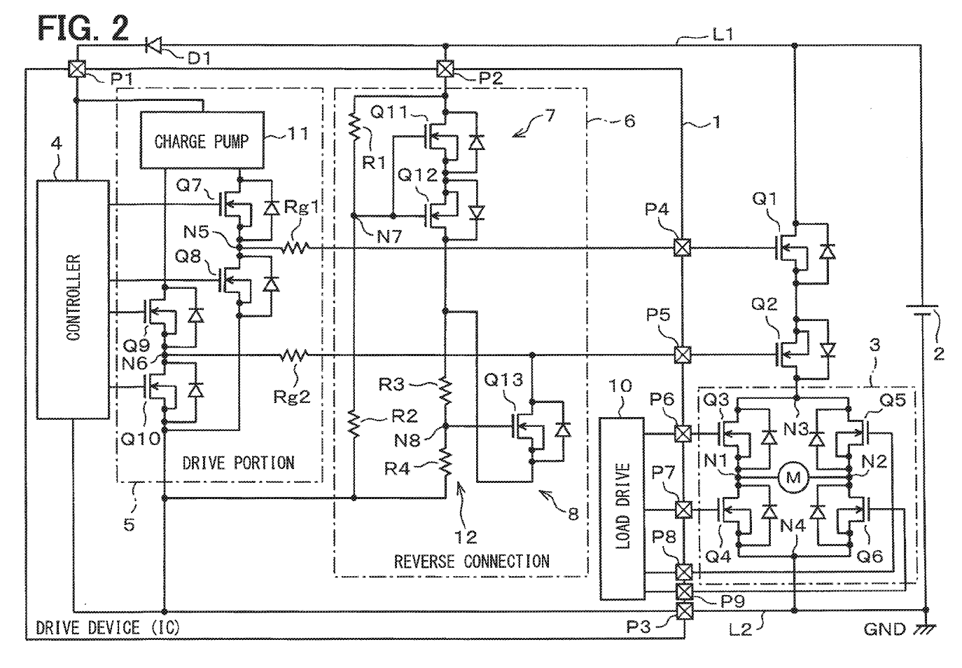

For example, a configuration shown in FIG. 2 is adoptable as a specific configuration of the drive device 1 having this function. FIG. 2 shows, by way of example, a case where the load 3 is constituted by a motor M and a drive circuit for driving the motor M. In this case, the drive circuit is an H-bridge circuit constituted by four transistors Q3 to Q6.

Each of the transistors Q3 to Q6 is an N channel type MOS transistor, and has a parasitic diode connected between the drain and source of the transistor with the anode provided on the source side. In this case, an interconnection node N1 of the transistors Q3 and Q4 is connected to one terminal of the motor M, while an interconnection node N2 of the transistors Q5 and Q6 is connected to the other terminal of the motor M. An interconnection node N3 of the transistors Q3 and Q5 is connected to the drain of the transistor Q2, while an interconnection node N4 of the transistors Q4 and Q6 is connected to the power supply line L2.

The drive device 1 includes a load drive portion 10 that drives the load 3 thus configured. Similarly to the drive portion 5, the load drive portion 10 operates by receiving power supplied from the direct current power supply 2 via the terminals P1 and P3. The load drive portion 10 generates gate driving signals for driving the transistors Q3 to Q6. These gate driving signals are applied to the respective gates of the transistors Q3 to Q6 via terminals P6 to P9, respectively. While not shown in the figures, an output stage for outputting the respective gate driving signals is constituted by a half bridge circuit including two N channel type MOS transistors.

The drive portion 5 includes a charge pump circuit 11, transistors Q7 to Q10, and gate resistors Rg1 and Rg2. The charge pump circuit 11 boosts voltage supplied via the terminal P1, and outputs the boosted voltage. Each of the transistors Q7 to Q10 is an N channel type MOS transistor, and has a parasitic diode connected between the drain and source of the transistor with the anode provided on the source side.

The drain of the transistor Q7 is connected to an output terminal of the charge pump circuit 11, while the source of the transistor Q7 is connected to the drain of the transistor Q8. The source of the transistor Q8 is connected to the terminal P3. The drain of the transistor Q9 is connected to the output terminal of the charge pump circuit 11, while the source of the transistor Q9 is connected to the drain of the transistor Q10. The source of the transistor Q10 is connected to the terminal P3.

An interconnection node N5 of the transistors Q7 and Q8 constitutes an output terminal for outputting gate driving signals associated with the transistor Q1, and is connected to the terminal P4 via the gate resistor Rg1. An interconnection node N6 of the transistors Q9 and Q10 constitutes an output terminal for outputting gate driving signals associated with the transistor Q2, and is connected to the terminal P5 via the gate resistor Rg2. The controller 4 controls driving of the transistors Q7 to Q10 of the drive portion 5.

The reverse connection protection controller 6 includes resistors R1 to R4 and transistors Q11 to Q13. A series circuit of the resistors R1 and R2 is connected between the terminal P2 and the terminal P3. Each of the transistors Q11 to Q13 is an N channel type MOS transistor, and has a parasitic diode connected between the drain and source of the transistor with the anode provided on the source side. The drain of the transistor Q11 is connected to the terminal P2, while the source of the transistor Q11 is connected to the source of the transistor Q12. The drain of the transistor Q12 is connected to the terminal P3 via a series circuit of the resistors R3 and R4.

The respective gates of the transistors Q11 and Q12 are connected to an interconnection node N7 of the resistors R1 and R2. The drain of the transistor Q13 is connected to the terminal P5, while the source of the transistor Q13 is connected to the drain of the transistor Q12. The gate of the transistor Q13 is connected to an interconnection node N8 of the resistors R3 and R4.

In the present embodiment, each resistance value is set such that the resistance value of the resistor R1 becomes considerably higher than the resistance value of the resistor R2. Specifically, the respective resistance values are set such that the voltage of the interconnection node N7 becomes substantially the voltage level of the direct current power supply 2 (e.g., 12 V) during reverse connection, and becomes substantially 0 V in the normal condition. Respective resistance values of the resistors R3 and R4 are set such that the voltage between the gate and source of the transistor Q13 becomes a voltage equal to or higher than a threshold voltage for turning on the transistor Q13 during reverse connection.

According to this configuration, the potential relationship detection portion 7 is constituted by the resistors R1, R2 and the transistors Q11 and Q12, while the potential fixing portion 8 is constituted by the resistors R3 and R4 and the transistor Q13. The transistor Q13 constituting the potential fixing portion 8 corresponds to a switch for opening and closing between the gate of the transistor Q2 and the power supply line L1. The resistors R3 and R4 constituting the potential fixing portion 8 correspond to the switch controller 12 which turns off the transistor Q13 in response to detection of the normal potential relationship by the potential relationship detection portion 7, and turns on the transistor Q13 in response to detection of the reverse potential relationship.

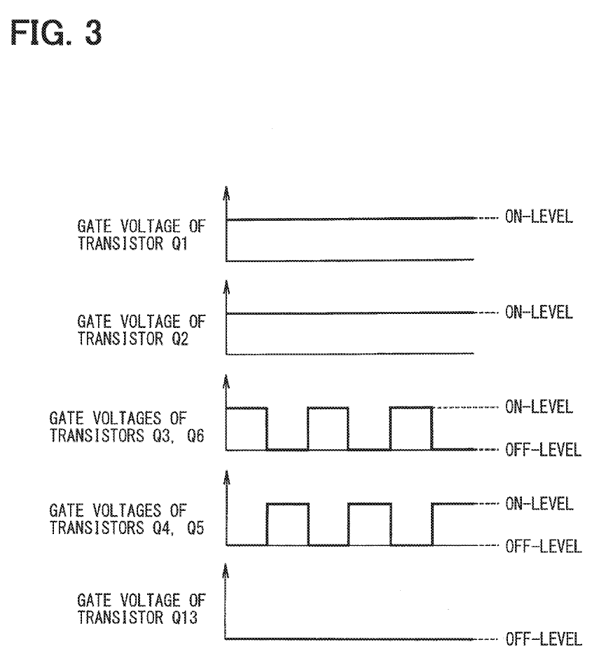

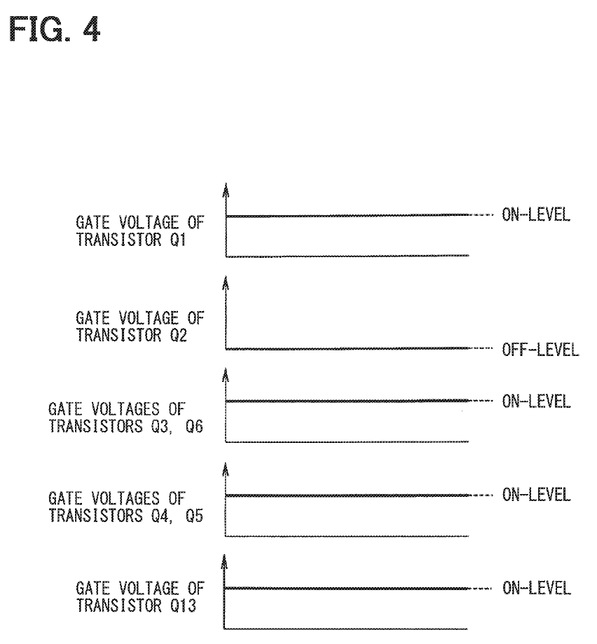

Operation of the configuration described above will be now described with reference to FIGS. 3 and 4. In the following description, it is assumed that the voltage value of the direct current power source 2 is 12 V, for example.

[1] Normal Operation

In this case, the high potential side terminal and the low potential side terminal of the direct current power supply 2 are correctly connected with each other. Accordingly, the potential of the power supply line L1 becomes 12 V, while the potential of the power supply line L2 becomes 0 V. In other words, the potential relationship between the power supply lines L1 and L2 is the normal potential relationship. Power is therefore normally supplied to the controller 4, the drive portion 5, and the load drive portion 10. Accordingly, the controller 4, the drive portion 5, and the load drive portion 10 are each in a normal operation condition.

In this case, the drive portion 5 outputs gate driving signals for turning on the transistors Q1 and Q2. As a result, the gate voltages of the transistors Q1 and Q2 each reach an ON-level. Therefore the transistors Q1 and Q2 are turned on as shown in FIG. 3. The load drive portion 10 drives the transistors Q3 to Q6 in accordance with a desired energization state of the motor M.

In this case, as shown in FIG. 3, the gate voltages of the transistors Q4 and Q5 each reach an OFF-level in a period of an ON-level of the gate voltages of the transistors Q3 and Q6. The gate voltages of the transistors Q4 and Q5 each reach an ON-level in a period of an OFF-level of the gate voltages of the transistors Q3 and Q6. In other words, the transistors Q3 and Q6 and the transistors Q4 and Q5 are complementarily turned on and off.

In this case, the voltage of the node N7 becomes substantially 0 V. The transistors Q11 and Q12 are turned off. As the transistors Q11 and Q12 are turned off, the source voltage of the transistor Q13 becomes 0 V that is the voltage of the power supply line L2. As shown in FIG. 3, the gate voltage of the transistor Q13 also becomes 0 V (OFF-level) that is the voltage of the power supply line L2. Accordingly, the transistor Q13 is turned off. In this manner, the transistor Q13 is turned off in the normal condition. The reverse connection protection controller 6 does not prevent the drive portion 5 from turning on the transistor Q2.

[2] Operation for Reverse Connection

In this case, the high potential side terminal and the low potential side terminal of the direct current power supply 2 are incorrectly connected with each other. Accordingly, the potential of the power supply line L1 becomes 0 V, while the potential of the power supply line L2 becomes 12 V. In other words, the potential relationship between the power supply lines L1 and L2 becomes the reverse potential relationship. In this case, power is not normally supplied to the controller 4, the drive portion 5, and the load drive portion 10. Accordingly, normal operation of each of the controller 4, the drive portion 5, and the load drive portion 10 becomes difficult.

Particularly in this case, the transistor Q2 is difficult to turn off by the drive portion 5. More specifically, the source of the transistor Q2 is connected to the source of the transistor Q1. In this case, the source voltage of the transistor Q2 becomes a voltage (e.g., 0.7 V) higher than 0 V that is the potential of the power supply line L1, by a forward voltage of the parasitic diode of the transistor Q1.

On the other hand, the gate voltage of the transistor Q2 becomes a voltage (e.g., 11.3 V) lower than 12 V that is the potential of the power supply line L2, by a forward voltage of the parasitic diode of the transistor Q10. As a result, the voltage between the gate and source of the transistor Q2 becomes equal to or higher than a threshold voltage Vt, and turns on the transistor Q2.

In this case, the transistors Q3 to Q6 are difficult to turn off by the load drive portion 10. The transistors Q3 to Q6 are difficult to turn off for a reason similar to the above-mentioned reason why the transistor Q2 is difficult to turn off by the drive portion 5. In this case, the gate voltages of the transistors Q3 to Q6 each reach an ON-level. The transistors Q3 to Q6 are turned on as shown in FIG. 4.

Accordingly, during reverse connection, an excessive current may flow through a path in an order of the “power supply line L2, the transistor Q4, the transistor Q3, the transistor Q2, the transistor Q1, and the power supply line L1”, and a path in an order of the “power supply line L2, the transistor Q6, the transistor Q5, the transistor Q2, the transistor Q1, and the power supply line L1”.

When such an excessive current flows, circuit elements may be broken by heat generated from the elements of the transistors Q1 to Q6. According to the present embodiment, however, a following operation performed by the reverse connection protection controller 6 prevents the flow of the excessive current. In this case, the voltage of the node N7 becomes approximately 12 V. The transistors Q11 and Q12 are turned on.

As the transistors Q11 and Q12 are turned on, a current flows through a path in an order of the “terminal P3, the resistor R4, the resistor R3, the transistor Q12, and (parasitic diode of) the transistor Q11”. The current flowing at this time is limited to a relatively small current by the resistors R3 and R4. With the flow of the current, the voltage of the node N8, that is, the gate voltage of the transistor Q13 reaches an ON-level. The transistor Q13 is turned on as shown in FIG. 4.

As a result, the gate voltage of the transistor Q2 becomes a voltage (e.g., 0.7 V) higher than 0 V that is the voltage of the power supply line L1, by a forward voltage of the parasitic diode of the transistor Q11. In this case, the gate voltage of the transistor Q2 reaches an OFF-level. The transistor Q2 is turned off as shown in FIG. 4. As described above, during reverse connection, the reverse connection protection controller 6 forcibly turns off the transistor Q2 even under driving of the transistor Q2 by the drive portion 5. As a result, each of the above-described paths is interrupted, in which condition a flow of excessive current can be stopped. The parasitic diode of the transistor Q2 is connected in such a manner that the cathode is provided on the power supply line L2 side. Accordingly, the operation described above can also prevent generation of a reverse current via the parasitic diode of the transistor Q2.

According to the present embodiment described above, following effects can be obtained.

During reverse connection of the direct current power supply 2 in the present embodiment, the potential relationship between the power supply lines L1 and L2 becomes the reverse potential relationship that is a reverse of the normal potential relationship between the power supply lines L1 and L2. In this case, the reverse connection protection controller 6 executes the protection operation for forcibly turning off the transistor Q2 even under driving by the drive portion 5 to cut off a current flowing through the power supply path. Accordingly, the transistor Q2 is turned off even when the drive portion 5 does not normally operate. The path through which the reverse current generated by reverse connection flows is thus interrupted. According to the present embodiment, therefore, a current flowing during reverse connection can be securely cut off. Accordingly, even when the direct current power supply 2 is reversely connected by error, breakage of the circuit elements including the transistors Q1 to Q6 is avoidable.

The resistors R3 and R4 of the reverse connection protection controller 6 limit the current flowing during reverse connection, allowing only a relatively small current to flow. In this case, each of the transistors Q11 to Q13 constituting the reverse connection protection controller 6 may be a transistor of a comparatively small size allowing only a flow of a small current. According to the present embodiment, therefore, reliable cutoff of the current flowing during reverse connection, and reduction of widening of a circuit area and a rise of costs can be both achieved.

The potential relationship detection portion 7 is configured to divide the voltages of the power supply lines L1 and L2 by the resistors R1 and R2 and detect the potential relationship between the power supply lines L1 and L2 based on the divided voltages. In this manner, the potential relationship can be detected by a simple circuit configuration. Accordingly, the foregoing effect of reduction of widening of the circuit area and the rise of costs further enhances.

When the reverse potential relationship between the power supply lines L1 and L2 is detected by the potential relationship detection portion 7, the potential fixing portion 8 fixes the gate potential of the transistor Q2 constituted by an N channel type MOS transistor to the potential of the power supply line L1. In this manner, the gate voltage of the transistor Q2 can securely reach the OFF-level (0 V) to turn off the transistor Q2 during reverse connection.

### Second Embodiment

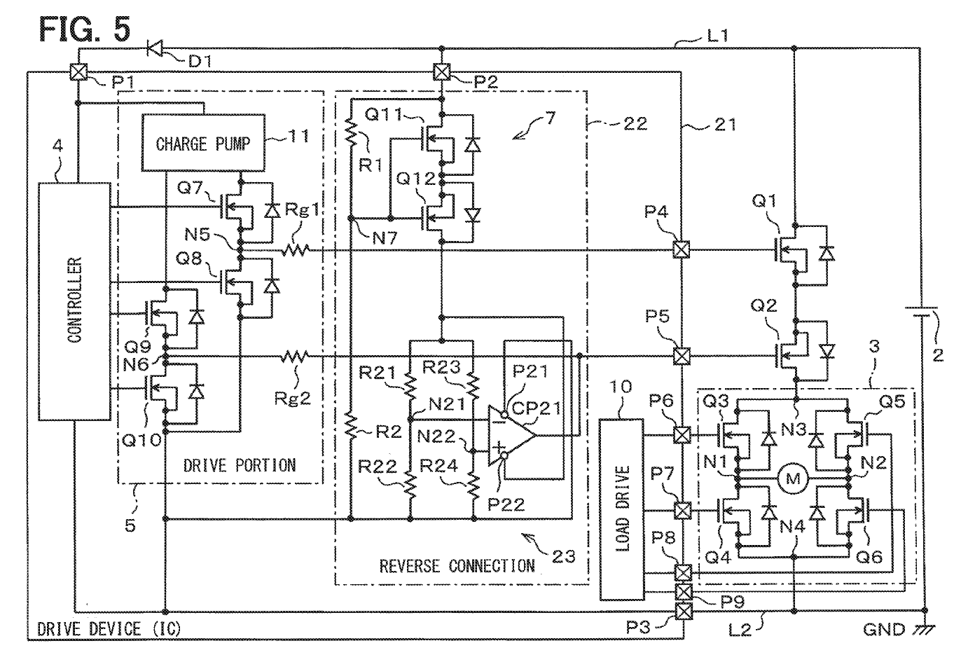

A second embodiment will be described with reference to FIG. 5.

As shown in FIG. 5, a drive device 21 of the present embodiment is different from the drive device 1 of the first embodiment in that a reverse connection protection controller 22 is provided in place of the reverse connection protection control portion 6. The reverse connection protection controller 22 is different from the reverse connection protection controller 6 in the configuration of the potential fixing portion. In this case, a potential fixing portion 23 includes resistors R21 to R24 and a comparator CP21.

A series circuit of the resistors R21 and R22 and a series circuit of the resistors R23 and R24 are connected between the drain of the transistor Q12 and the terminal P3. An interconnection node N21 of the resistors R21 and R22 is connected to an inverting input terminal of the comparator CP21, while an interconnection node N22 of the resistors R23 and R24 is connected to a non-inverting input terminal of the comparator CP21.

An output terminal of the comparator CP21 is connected to the terminal P5. The comparator CP21 includes a power supply terminal P21 for receiving operation power supply, and a ground terminal P22. The power supply terminal P21 is connected to the terminal P3, while the ground terminal P22 is connected to the drain of the transistor Q12.

According to this configuration, the comparator CP21 receives operation power supply and comes into an operable operation state when the transistors Q11 and Q12 are turned on with the reverse potential relationship produced between the power supply lines L1 and L2. More specifically, the comparator CP21 comes into the operation state when the transistors Q11 and Q12 are turned on in response to detection of the reverse potential relationship between the power supply lines L1 and L2 by the potential relationship detection portion 7 in the reverse connection condition where reverse connection is caused.

When the transistors Q11 and Q12 are turned off, the comparator CP21 is brought into a non-operation state by a stop of the operation power supply. More specifically, the comparator CP21 comes into the non-operation state when the transistors Q11 and Q12 are turned off in response to detection of the normal potential relationship between the power supply lines L1 and L2 by the potential relationship detection portion 7 in the normal condition where reverse connection is not caused.

Resistance values of the resistors R21 to R24 are set to such values that the voltage of the interconnection node N21 becomes higher than the voltage of the interconnection node N22 during reverse connection. Accordingly, during reverse connection, the comparator CP21 comes into the operation state, and outputs an output signal at a voltage level of 0 V.

Operation of the configuration described above will be now described.

[1] Normal Operation

In this case, the controller 4, the drive portion 5, and the load drive portion 10 are each in the normal operation state similarly to the first embodiment. In this case, the voltage of the node N7 becomes substantially 0 V. The transistors Q11 and Q12 are turned off. As a result, the comparator CP21 comes into a non-operation state. The source voltage of the transistor Q13 becomes 0 V that is the voltage of the power supply line L2. As described above, the comparator CP21 is in the non-operation state in the normal condition. Accordingly, the reverse connection protection controller 22 does not prevent the drive portion 5 from turning on the transistor Q2.

[2] Operation for Reverse Connection

In this case, normal operation of each of the controller 4, the drive portion 5, and the load drive portion 10 is difficult similarly to the first embodiment. In this case, the voltage of the node N7 becomes substantially 12 V. The transistors Q11 and Q12 are turned on. As a result, the comparator CP21 comes into the operation state, and outputs an output signal at a voltage level of 0 V. Accordingly, the gate voltage of the transistor Q2 reaches an OFF-level (0 V). The transistor Q2 is turned off. As described above, during reverse connection, the reverse connection protection controller 22 forcibly turns off the transistor Q2 even under driving of the transistor Q2 by the drive portion 5. Accordingly, the current path from the power supply line L2 to the power supply line L1 is interrupted, in which condition a flow of an excessive current can be stopped.

As described above, similarly to the reverse connection protection controller 6 of the first embodiment, the reverse connection protection controller 22 of the present embodiment forcibly turns off the transistor Q2 even under driving by the drive portion 5 during reverse connection to execute the protection operation for cutting off the current flowing through the power supply path. Accordingly, the current flowing during reverse connection can be securely cut off also in the present embodiment. Therefore effects similar to those of the first embodiment can be produced.

### Third Embodiment

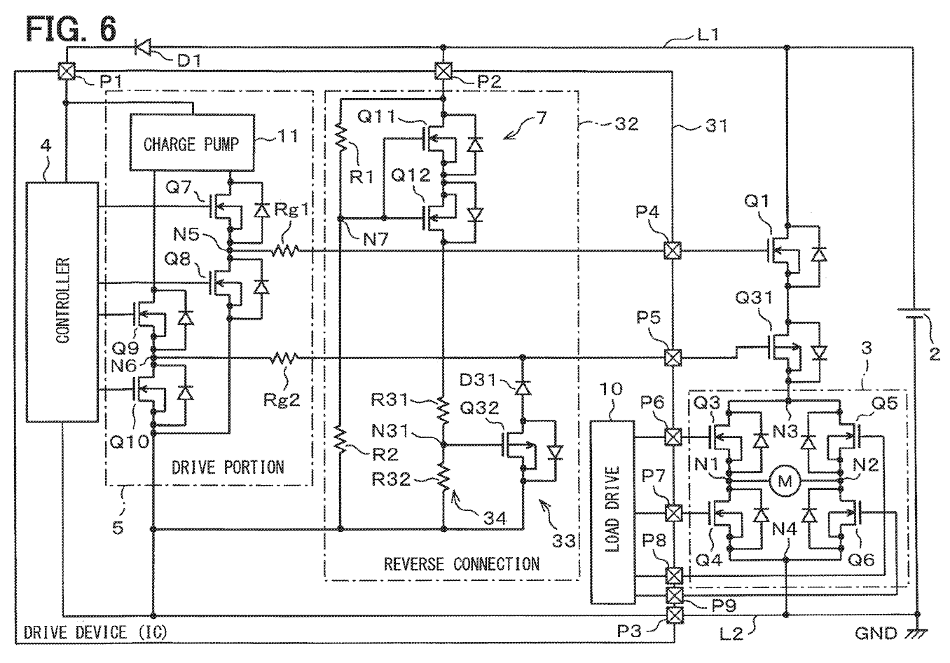

A third embodiment will be described with reference to FIG. 6.

As shown in FIG. 6, a drive device 31 of the present embodiment controls driving of the transistors Q1 and Q31 interposed in series in the power supply path extending from the direct current power supply 2 to the load 3. The transistor Q31 is a P channel type MOS transistor, and has a parasitic diode connected between the drain and source of the transistor with the anode provided on the drain side.

The drain of the transistor Q1 is connected to the power supply line L1, and the source of the transistor Q1 is connected to the drain of the transistor Q31. The source of the transistor Q31 is connected to the power supply line L2 via the load 3. In this manner, the transistors Q1 and Q31 are connected so that the parasitic diodes are directed oppositely to each other. In the present embodiment, the transistor Q31 corresponds to the protection MOS transistor.

The drive device 31 is different from the drive device 1 of the first embodiment in that a reverse connection protection controller 32 is provided in place of the reverse connection protection control portion 6. The reverse connection protection controller 32 is different from the reverse connection protection controller 6 in the configuration of the potential fixing portion. In this case, the potential fixing portion 33 includes resistors R31 and R32, a transistor Q32, and a diode D31.

The drain of the transistor Q12 is connected to the terminal P3 via a series circuit of the resistors R31 and R32. The transistor Q32 is a P channel type MOS transistor, and has a parasitic diode connected between the drain and source of the transistor with the anode provided on the drain side. The gate of the transistor Q31 is connected to an interconnection node N31 of the resistors R31 and R32. The drain of the transistor Q32 is connected to the terminal P5 via the diode D31 in the forward direction. The source of the transistor Q32 is connected to the terminal P3.

Respective resistance values of the resistors R31 and R34 are set to such values that the voltage between the source and gate of the transistor Q32 becomes a voltage equal to or higher than a threshold voltage for turning on the transistor Q31 during reverse connection. In the present embodiment, the transistor Q32 corresponds to a switch for opening and closing between the gate of the transistor Q2 and the power supply line L1. The resistors R31 and R32 correspond to a switch controller 34 which turns off the transistor Q32 in response to detection of the normal potential relationship by the potential relationship detection portion 7, and turns on the transistor Q32 in response to detection of the reverse potential relationship.

Operation of the configuration described above will be now described.

[1] Normal Operation

In this case, the controller 4, the drive portion 5, and the load drive portion 10 are each in the normal operation state similarly to the first embodiment. In this case, the voltage of the node N7 becomes substantially 0 V, and therefore the transistors Q11 and Q12 are turned off. As the transistors Q11 and Q12 are turned off, each of the source voltage and gate voltage of the transistor Q32 becomes 0 V that is the voltage of the power supply line L2. Accordingly, the transistor Q32 is turned off. In this manner, the transistor Q32 is turned off in the normal condition. Accordingly, the reverse connection protection controller 32 does not prevent the drive portion 5 from turning on the transistor Q31.

[2] Operation for Reverse Connection

In this case, normal operation of each of the controller 4, the drive portion 5, and the load drive portion 10 is difficult similarly to the first embodiment. In this case, the voltage of the node N7 becomes substantially 12 V, and therefore the transistors Q11 and Q12 are turned on. As the transistors Q11 and Q12 are turned on, a current flows through a path in an order of the “terminal P32, resistor R32, resistor R31, transistor Q12, and (parasitic diode of) transistor Q11”. The current flowing at this time is limited to a relatively small current by the resistors R31 and R32.

With the flow of the current, the voltage between the source and gate of the transistor Q32 becomes a voltage equal to or higher than a threshold voltage, and therefore the transistor Q32 is turned on. As a result, the gate voltage of the transistor Q31 becomes a voltage lower than 12 V that is the voltage of the power supply line L2, by a forward voltage of the diode D31. Accordingly, the gate voltage of the transistor Q31 reaches an OFF-level, and the transistor Q31 is turned off. As described above, during reverse connection, the reverse connection protection controller 32 forcibly turns off the transistor Q31 even under driving of the transistor Q31 by the drive portion 5. Accordingly, the current path from the power supply line L2 to the power supply line L1 is interrupted, in which condition a flow of an excessive current can be stopped.

As described above, similarly to the reverse connection protection controller 6 of the first embodiment, the reverse connection protection controller 32 of the present embodiment forcibly turns off the transistor Q31 even under driving by the drive portion 5 during reverse connection to execute the protection operation for cutting off the current flowing through the power supply path. Accordingly, the current flowing during reverse connection can be securely cut off also in the present embodiment, and therefore effects similar to those of the first embodiment can be produced.

Moreover, the potential fixing portion 33 of the reverse connection protection controller 32 includes the diode D31. The diode D31 is provided for a following reason. When the drain of the transistor Q32 is directly connected to the terminal P5 without interposition of the diode D31, a current path from the terminal P5, that is, the gate of the transistor Q31 to the power supply line L2 via the parasitic diode of the transistor Q32 is formed. In this case, the reverse connection protection controller 32 may prevent the drive portion 5 from turning on the transistor Q31 in the normal condition. However, when the diode D31 is connected between the drain of the transistor Q32 and the terminal P5 with the anode provided on the transistor Q32 side as in the present embodiment, the reverse connection protection controller 32 does not prevent the drive portion 5 from turning on the transistor Q31 in the normal condition.

When the reverse potential relationship between the power supply lines L1 and L2 is detected by the potential relationship detection portion 7, the potential fixing portion 33 fixes the gate potential of the transistor Q31, which is a P channel type MOS transistor, to the potential of the power supply line L2. In this manner, the gate voltage of the transistor Q31 can be securely brought to the OFF-level (about 12 V) to turn off the transistor Q31 during reverse connection.

### Other Embodiments

The present disclosure is not limited to the embodiments described above and illustrated in the drawings. Any modifications, combinations, or expansions may be made without departing from the subject matters of the present disclosure.

The specific configuration of the reverse connection protection controller may not be limited to the configurations described above by way of example in the embodiments. The reverse connection protection controller may have any configurations as long as the protection operation for forcibly turning off the transistor Q2 can be executed even under driving by the drive portion 5 to cut off a current flowing through the power supply path extending from the direct current power supply 2 to the load 3 when the potential relationship between the power supply lines L1 and L2 becomes the reverse potential relationship that is a reverse of the normal potential relationship.

The load 3 may have configurations other than the configuration shown in FIG. 2 and others. For example, the load 3 may be a resistive load, an inductive load, or the like, or may be constituted by a three-phase motor and a drive circuit that drives the three-phase motor.

While the present disclosure has been described with reference to embodiments thereof, it is to be understood that the disclosure is not limited to the embodiments and constructions. The present disclosure is intended to cover various modification examples and equivalents thereof. In addition, while the various elements are shown in various combinations and configurations, which are exemplary, other combinations and configurations, including more, less or only a single element, are also within the spirit and scope of the present disclosure.

1. A drive device that controls driving of an opening/closing metal-oxide-semiconductor (MOS) transistor and a protection MOS transistor interposed in series in a power supply path extending from a direct current power supply to a load, and connected so that parasitic diodes of the opening/closing MOS transistor and the protection MOS transistor are directed oppositely to each other, the drive device comprising:
a drive portion that operates by receiving power supplied from the direct current power supply via a high potential side power supply line connected to a high potential side terminal of the direct current power supply and a low potential side power supply line connected to a low potential side terminal of the direct current power supply, and drives the opening/closing MOS transistor and the protection MOS transistor; and
a reverse connection protection controller that executes a protection operation which cuts off a current flowing in the power supply path by forcibly turning off the protection MOS transistor independently of driving by the drive portion in response to that a potential relationship between the high potential side power supply line and the low potential side power supply line becomes a reverse potential relationship that is a reverse of a normal potential relationship between the high potential side power supply line and the low potential side power supply line,
wherein:
the reverse connection protection controller includes a potential relationship detection portion that divides a voltage between the high potential side power supply line and the low potential side power supply line, and detects a potential relationship between the high potential side power supply line and the low potential side power supply line based on the divided voltages;
the reverse connection protection controller executes the protection operation based on a detection result obtained by the potential relationship detection portion;
the potential relationship detection portion includes a series circuit of resisters connected between the high potential side power supply line and the low potential side power supply line;
the potential relationship detection portion includes a transistor connected between the high potential side power supply line and the low potential side power supply line and turned on and off based on the divided voltages which are voltage of an interconnection node of the resistors; and
the turning on and off of the transistor expresses the detection result of the potential relationship.

2. The drive device according to claim 1, wherein:
the protection MOS transistor is of an N channel type; and
the reverse connection protection controller includes a potential fixing portion that fixes a gate potential of the protection MOS transistor to a potential of the high potential side power supply line when the potential relationship detection portion detects the reverse potential relationship.

3. The drive device according to claim 1, wherein:
the protective MOS transistor is of a P channel type; and
the reverse connection protection controller includes a potential fixing portion that fixes a gate potential of the protection MOS transistor to a potential of the low potential side power supply line when the potential relationship detection portion detects the reverse potential relationship.

4. The drive device according to claim 2, wherein:
the potential fixing portion includes
a switch to open and close between a gate of the protection MOS transistor and the high potential side power supply line, and
a switch controller that turns off the switch in response to detection of the normal potential relationship by the potential relationship detection portion, and turns on the switch in response to detection of the reverse potential relationship by the potential relationship detection portion.

5. The drive device according to claim 3, wherein:
the potential fixing portion includes
a switch to open and close between a gate of the protection MOS transistor and the low potential side power supply line, and
a switch controller that turns off the switch in response to detection of the normal potential relationship by the potential relationship detection portion, and turns on the switch in response to detection of the reverse potential relationship by the potential relationship detection portion.

6. The drive device according to claim 2, wherein:
the potential fixing portion includes a comparator that comes into a non-operation state in response to detection of the normal potential relationship by the potential relationship detection portion, and comes into an operation state in response to detection of the reverse potential relationship by the potential relationship detection portion.
